(19) United States
(12) Patent Application Publication
(10) Pub. No.: US 2013/0314855 A1
(43) Pub. Date: Nov. 28, 2013

(54) SUPPORT MECHANISM AND ELECTRONIC DEVICE USING SAME

(71) Applicants: SHENZHEN FUTAIHONG PRECISION INDUSTRY CO., LTD., Shenzhen (CN); FIH (HONG KONG) LIMITED, Kowloon (HK)

(72) Inventor: GANG YANG, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/730,878

(22) Filed: Dec. 29, 2012

(30) Foreign Application Priority Data
May 28, 2012 (CN) 201210168050.1

(51) Int. Cl. A47F 5/10; H05K 5/02

(52) U.S. Cl. CPC A47F 5/10; H05K 5/0217
USPC 361/679.01; 248/464

(57) ABSTRACT

A support mechanism includes a main frame, two connecting portions, and two support rods. The main frame includes two opposite side parts, two opposite bent parts, and a connecting part integrally formed together. Each bent part is connected between each side part and one end of the connecting part, and a latching space is defined between the connecting part and the side parts for latching an electronic device. The two connecting portions are rotatably fitted around the side parts, and the two support rods are connected to the connecting portions.

### BACKGROUND

1. Technical Field

The exemplary disclosure relates to support mechanisms, particularly to support mechanisms used in electronic devices.

2. Description of Related Art

Some portable electronic products have a bracket on the back of its casing. Thus, when the bracket is opened, the portable electronic product becomes supported and is able to sit on the desk or other supporting surface to make it more comfortable for the users to view the displays.

However, typical brackets of the existing portable electronic products have a complicated structure and are difficult to manufacture and use.

Therefore, there is room for improvement within the art.

### BRIEF DESCRIPTION OF THE DRAWINGS

Many aspects of the exemplary support mechanism and electronic device using the support mechanism can be better understood with reference to the following drawings. These drawings are not necessarily drawn to scale, the emphasis instead being placed upon clearly illustrating the principles of the present support mechanism and electronic device. Moreover, in the drawings like reference numerals designate corresponding parts throughout the several views. Wherever possible, the same reference numbers are used throughout the drawings to refer to the same or like elements of an embodiment.

FIG. 1 is a schematic view of a support mechanism according to an exemplary embodiment.

FIG. 2 is an exploded view of the support mechanism shown in FIG. 1.

FIGS. 3 and 4 are schematic views of the support mechanism used for supporting an electronic device in an open state.

FIG. 5 is similar to the FIG. 4, showing the support mechanism in a closed use.

### DETAILED DESCRIPTION

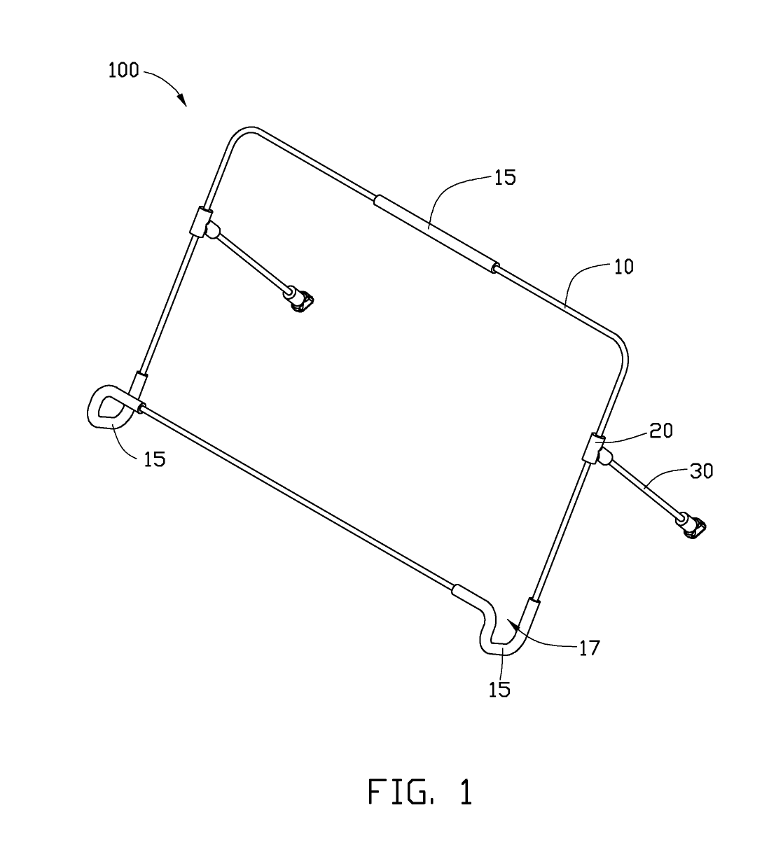

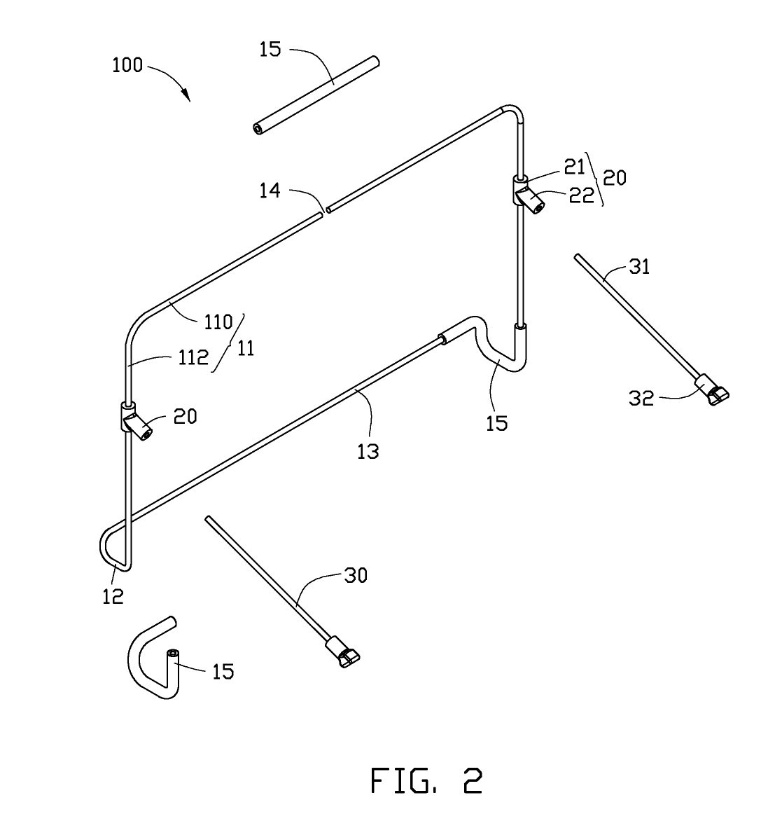

FIGS. 1 and 2 illustrate a support mechanism 100 used for electronic devices, such as tablet computer. The tablet computer is merely an exemplary application, for the purposes of describing details of the support mechanism 100. The support mechanism 100 comprises a main frame 10, two connecting portions 20 and two support rods 30.

The main frame 10 is substantially rectangular, and is a symmetrically bent metal wire. In this exemplary embodiment, the main frame 10 is made of spring steel, and comprises two opposite side parts 11, two opposite bent parts 12, and a connecting part 13 integrally formed together. Each side part 11 is substantially L-shaped, and comprises a horizontal section 110 and a vertical section 112 substantially perpendicular to the horizontal section 110. A clearance 14 is defined between opposite ends of the horizontal sections 110. Each bent part 12 is connected to each side part 11 and one end of the connecting part 13. Each bent part 12 first extends from a distal end of the vertical section 112 along a direction perpendicular to the vertical section 112, and then extends upwardly to the connecting part 13 along a direction parallel to the vertical section 112. Opposite ends of the connecting part 13 is connected to the bent parts 12 so that the connecting part 13 is not coplanar with the side parts 11. Thus, a latching space 17 is defined between the connecting part 13 and the side parts 11, for latching an electronic device. In this exemplary embodiment, the main frame 10 comprises three tubes 15. The tubes 15 are made of soft material, such as thermoplastic polyurethane (TPU) or silicon. Two of the tubes 15 are fitted around the bent parts 12 from the clearance 14 on the main frame 10. The remaining tube 15 is fitted around opposite ends of the horizontal sections 110 for shielding the clearance 14.

Each connecting portion 20 is used for connecting the support rods 30 to the main frame 10. The connecting portions 20 are made of TPU. In this exemplary embodiment, each connecting portion 20 comprises a first hollow sleeve 21 and a second hollow sleeve 22 perpendicularly extending from the first hollow sleeve 21. Each first sleeve 21 can be rotatably fitted around the vertical section 112 from the clearance 14, and can be positioned at a predetermined position by friction.

Each support rod 30 has a rod body 31 and a cushion foot 32. A first end of the rod body 31 is configured for latching in the second hollow sleeve 22, and a second end of the rod body 31 is fitted around the cushion foot 32. In this exemplary embodiment, the cushion feet 32 are made of thermoplastic polyurethane (TPU) or silicon.

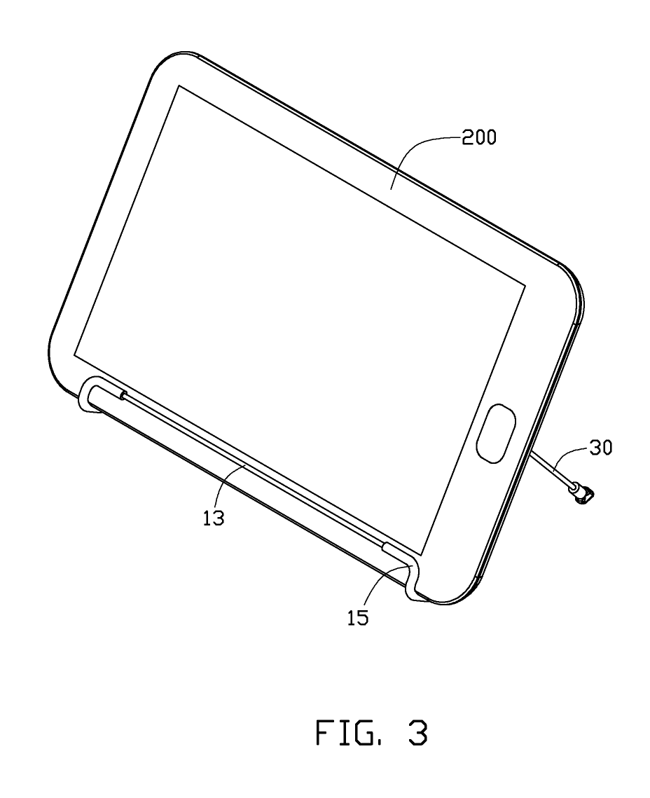

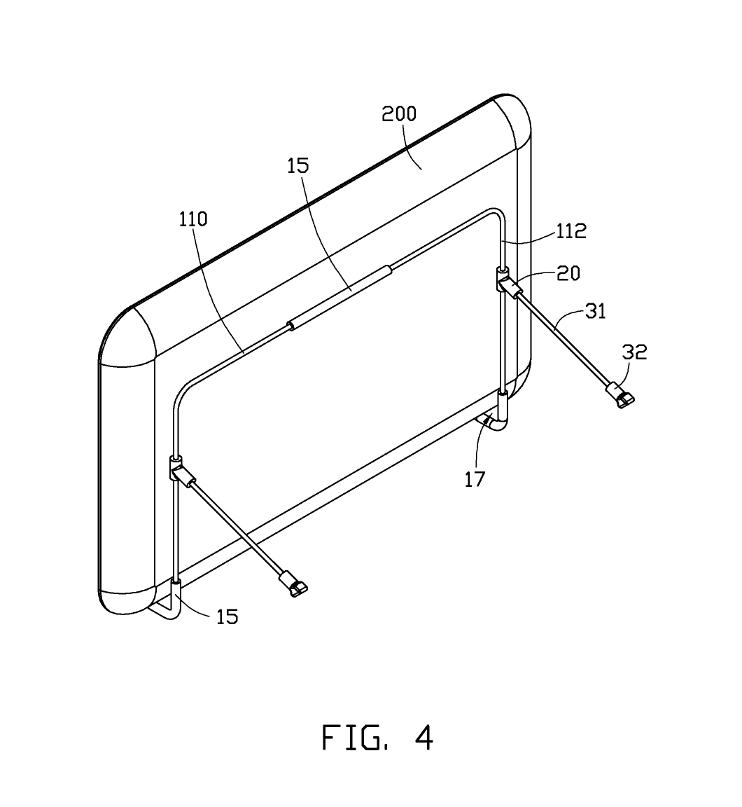

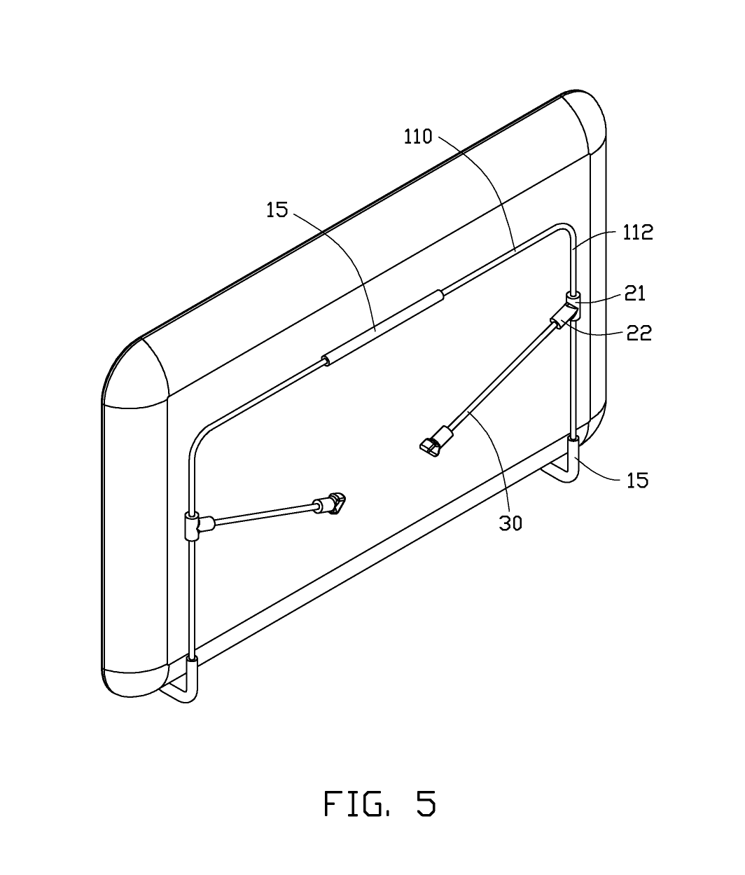

FIGS. 3 and 4 show the support mechanism 100 configured for supporting an electronic device 200 such as tablet computer. The support mechanism 100 is positioned on a surface, and the tubes 15 on the bent parts 12 and the cushion feet 32 contact the surface. A first end of the electronic device 200 is positioned in the latching space 17, and a second end of the electronic device 200 is supported on the horizontal sections 110. Thus, the electronic device 200 is supported by the support mechanism 100 in a predetermined position. When the viewing angle of the electronic device 200 needs to be adjusted, the support rods 30 with the connecting portions 20 can be rotated until the electronic device 200 is at a comfortable viewing angle. When the support mechanism 100 is in a closed state like shown FIG. 5, the support rods 30 can be rotated to a back of the electronic device for making the electronic device 200 with the support mechanism 100 convenient to carry.

The present embodiment of the support mechanism 100 may conveniently support the electronic device 200 at a desired angle. Additionally, since the tubes 15 are positioned on the main frame 10, the metal main frame 10 is prevented from directly contacting with the electronic device 200.

Even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A support mechanism comprising:
a main frame comprising two opposite side parts, two opposite bent parts, and a connecting part integrally formed together; each of the two opposite bent parts connected between each of the two opposite side parts and one end of the connecting part, a latching space defined between the connecting part and the two opposite side parts configured for latching an electronic device;
two connecting portions rotatably fitted around the two opposite side parts; and
two support rods latched to the two connecting portions, and the two support rods, with the two connecting portions rotatably engaging with the two opposite side parts, configured for supporting the electronic device at a predetermined angle.

2. The support mechanism of claim 1, wherein each of the two opposite side parts comprises a horizontal section and a vertical section, perpendicular to the horizontal section; and a clearance is defined between opposite ends of the horizontal sections.

3. The support mechanism of claim 2, wherein each of the two opposite bent parts extend from a distal end of the vertical section, along a direction perpendicular to the vertical section, and extends upwardly to the connecting part, along a direction parallel to the vertical section.

4. The support mechanism of claim 3, wherein the main frame comprises three tubes, two of the tubes are fitted around the two opposite bent parts from the clearance on the main frame, and the remaining tube is fitted around opposite ends of the horizontal sections for shielding the clearance.

5. An electronic device, comprising:
a main frame comprising two opposite side parts, two opposite bent parts, and a connecting part integrally formed together; each of the two opposite bent parts connected between each of the two opposite side parts and one end of the connecting part, a latching space defined between the connecting part and the two opposite side parts;
two connecting portions rotatably fitted around the two opposite side parts; and
two support rods latched to the two connecting portions, the two support rods with the two connecting portions rotatably engaging with the two opposite side parts;
wherein:
when in a first state, the two support rods are with the two connecting portions are rotated relative to the two opposite side parts for supporting the electronic device at a predetermined angle;
when in a second state, the support rods are rotated to a back of the electronic device.

6. The electronic device of claim 5, wherein each of the two opposite side parts comprises a horizontal section and a vertical section, perpendicular to the horizontal section; and a clearance is defined between opposite ends of the horizontal sections.

7. The electronic device of claim 6, wherein each of the two opposite bent parts extend from a distal end of the vertical section, along a direction perpendicular to the vertical section, and extends upwardly to the connecting part, along a direction parallel to the vertical section.

8. The electronic device of claim 7, wherein the main frame comprises three tubes, two of the tubes are fitted around the two opposite bent parts from the clearance on the main frame, and the remaining tube is fitted around opposite ends of the horizontal sections for shielding the clearance.
